(19) United States
(12) Patent Application Publication
(10) Pub. No.: US 2024/0258453 A1
(43) Pub. Date: Aug. 1, 2024

(54) Manufacturing method of electronic device

(71) Applicant: InnoLux Corporation, Miao-Li County (TW)

(72) Inventor: Chun-Hui HUANG, Miao-Li County (TW)

(73) Assignee: InnoLux Corporation, Miao-Li County (TW)

(21) Appl. No.: 18/403,729

(22) Filed: Jan. 4, 2024

(30) Foreign Application Priority Data
Jan. 30, 2023 (TW) 112102905

(51) Int. Cl. H01L 33/00; H01L 27/15

(52) U.S. Cl. CPC H01L 33/005; H01L 27/156

(57) ABSTRACT

The disclosure provides a manufacturing method of an electronic device, which comprises providing a first substrate, the first substrate comprises a plurality of transfer regions, each transfer region comprises a plurality of electronic components, picking up a first group of electronic components from one of the transfer regions, and transferring the first group of electronic components to a target substrate, the diagonal length of the target substrate is L, and the first group of electronic components are arranged in a matrix, and a length M of the matrix in a horizontal direction is greater than or equal to 0.315 L and less than L.

### BACKGROUND OF THE DISCLOSURE

### 1. Field of the Disclosure

The present disclosure relates to the photoelectric field, in particular to a manufacturing method of an electronic device, which can reduce the probability of shot mura (uneven light) between disposing regions when performing mass transfer in the display manufacturing process.

### 2. Description of the Prior Art

As a necessary component of electronic products, light-emitting elements are widely used in displays of various electronic products, such as mobile phones, tablet computers, car displays and so on. When making a display, the completed light-emitting elements are often transferred from the wafer to the substrate of the display by mass transfer. However, in the process of making light-emitting elements, there may be a problem of uneven brightness of light-emitting elements (that is, some light-emitting elements have higher brightness, while others have lower brightness). After the above-mentioned light-emitting elements are transferred to the substrate of the display, it is easy to cause the problem of uneven brightness between different regions on the display, which can also be called shot mura, and the shot mura problem will cause the user's visual experience to decline. Therefore, methods are needed to improve the above-mentioned shot mura problem.

### SUMMARY OF THE DISCLOSURE

The present disclosure provides a manufacturing method of an electronic device, which comprises providing a first substrate, the first substrate comprises a plurality of transfer regions, each transfer region comprises a plurality of electronic components, picking up a first group of electronic components from one of the transfer regions, and transferring the first group of electronic components to a target substrate, the diagonal length of the target substrate is L, the first group of electronic components on the target substrate are arranged in a matrix, and the length M of the matrix in a horizontal direction is greater than or equal to 0.315 L and less than L.

The present disclosure also provides a manufacturing method of an electronic device, which comprises providing a first substrate, the first substrate comprises a plurality of transfer regions, each transfer region comprises a plurality of electronic components, picking up a first group of electronic components from one of the transfer regions, transferring the first group of electronic components to a first region on a target substrate, picking up a second group of electronic components from one of the transfer regions, and transferring the second group of electronic components to a second region on the target substrate, the first region and the second region are not adjacent to each other.

The present disclosure also provides a manufacturing method of an electronic device, which comprises providing a first substrate, the first substrate comprises a plurality of transfer regions, each transfer region comprises a plurality of electronic components, picking up a first group of electronic components from a first transfer region of the transfer regions, transferring the first group of electronic components to a first region on a target substrate, picking up a second group of electronic components from a second transfer region of the transfer regions, and transferring the second group of electronic components to a second region on the target substrate, the relative positions of the first transfer region and the second transfer region on the first substrate are the same as the relative positions of the first region and the second region on the target substrate.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 shows a top view schematic diagram of a wafer.

FIG. 2 is shows a top view schematic diagram of a substrate of a display.

FIG. 3 is a schematic diagram showing the distance between a display and a viewer.

FIG. 4 is a schematic diagram showing the distribution distance of the disposing region (shot) on a substrate in the horizontal direction.

FIG. 5 is a schematic diagram showing the distribution distance of the disposing region (shot) on a substrate in the vertical direction.

FIG. 6 shows a schematic diagram of a substrate after a mass transfer is performed according to an embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of an electronic device (i.e. a display device in this disclosure), and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present disclosure, the corresponding features, areas, steps, operations and/or components would be pointed to existence, but not limited to the existence of one or a plurality of the corresponding features, areas, steps, operations and/or components.

The terms “about”, “substantially”, “equal”, or “same” generally mean within 20% of a given value or range, or mean within 10%, 5%, 3%, 2%, 1%, or 0.5% of a given value or range.

In addition, the phrase “in a range from a first value to a second value” indicates the range includes the first value, the second value, and other values in between.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

It should be noted that the technical features in different embodiments described in the following can be replaced, recombined, or mixed with one another to constitute another embodiment without departing from the spirit of the present disclosure.

The electronic device disclosed in the present disclosure can include, for example, a display device, an antenna device, a sensing device, a touch display, a curved display or a free shape display, and can also be a bendable or flexibly spliced electronic device, but is not limited thereto. Electronic device may include, for example, light emitting diodes, liquid crystal, fluorescence, phosphorescence, quantum dot (QD), other suitable display media, or combinations of the foregoing, but are not limited thereto. The light-emitting diode (LED) may include, for example, an organic light-emitting diode (OLED), inorganic light-emitting diode, mini light-emitting diode (mini LED), micro light-emitting diode (micro LED) or quantum dot light-emitting diode (QDLED), or other suitable materials or any arrangement and combination of the above, but not limited thereto. The antenna device can be, for example, a liquid crystal antenna, but is not limited thereto. It should be noted that the electronic devices disclosed in this disclosure can be any combination of the above, but are not limited thereto. In addition, the appearance of the electronic device can be rectangular, circular, polygonal, with curved edges or other suitable shapes. An electronic device may have peripheral systems such as a driving system, a control system, a light source system, a shelf system, etc. to support a display device or an antenna device. Hereinafter, the display device will be used as an electronic device or a splicing device to illustrate the disclosure, but the disclosure is not limited to this.

As mentioned above, in the process of manufacturing a display, after the electronic components are completed on the first substrate, the electronic components on the first substrate are often transferred to the substrate of the display by the method of mass transfer. The first substrate described here can be a wafer or a carrier board carrying electronic components, and the electronic components can be, for example, light emitting diodes, but the disclosure is not limited to this. For clear explanation, the first substrate will be illustrated with a wafer and the electronic component will be illustrated with a light emitting diode as an example. However, in other embodiments of the present disclosure, the electronic component may include other components besides the light emitting diode, it can also be within the scope of the present disclosure.

However, in order to make the process simple and stable, the general mass transfer usually chooses to transfer the LEDs in the same region on the wafer repeatedly. More specifically, the manufactured light-emitting diodes on the wafer W are divided into several regions according to their distribution positions, and the light-emitting diodes (for example, the odd rows of light-emitting diodes are taken first, and then the even rows of light-emitting diodes are taken) are transferred to the adjacent positions on the display substrate in a specific order during the transfer, but this will make the optical variation in each region repeatedly and orderly seen by observers in a small range. As mentioned in the prior art, this brightness unevenness is also called shot mura. There may be a similar situation in other types of electronic components, because some characteristics of electronic components in an region may change with the location distribution. For example, if the resistance value of electronic components in the left half of a transfer region is high and the resistance value of electronic components in the right half is low, when a mass transfer is carried out, the characteristic distribution of this region will be copied to the substrate that accepts these electronic components, so that each block on the substrate that accepts electronic components from this region may also have the situation that the resistance value of electronic components in the left half is high and the resistance value of electronic components in the right half is low. If these blocks are concentrated in a small range on the substrate, it is easy to repeat the situation that the resistance value of electronic components in the left half is high and the resistance value of electronic components in the right half is low in this small range.

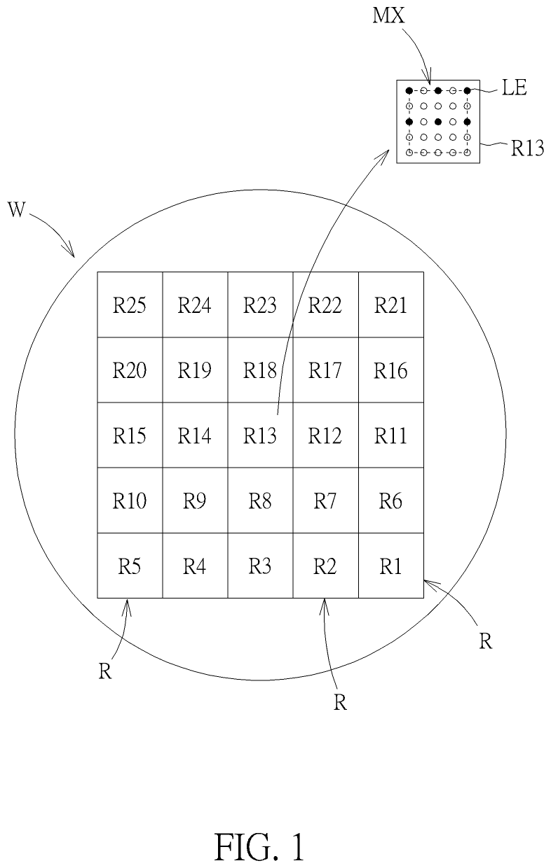

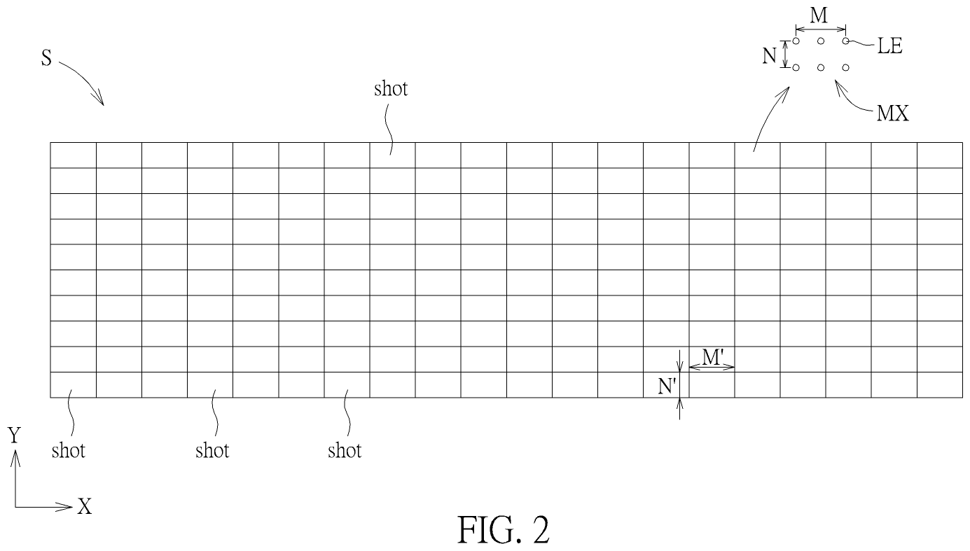

For the sake of clearer explanation, an example will be given in FIG. 1 and FIG. 2, in which FIG. 1 shows a top view of a wafer and FIG. 2 shows a top view of a substrate of a display. As shown in FIGS. 1 and 2, the wafer W includes a plurality of transfer regions R, and the substrate S of the display includes a plurality of disposing regions (shot), in which a plurality of electronic components (e.g., an electronic component matrix MX in which light emitting diodes LE are arranged) can be set. Among them, a plurality of transfer regions R contained on the wafer W can be numbered into transfer regions R1 to R25 for convenience, and each transfer region R contains a plurality of electronic components. The substrate S includes a grid matrix consisting of 20 columns and 10 rows, and each grid can be regarded as a disposing region (shot). In this embodiment, column are arranged along the Y direction, while rows are arranged along the X direction. It is worth noting that the number of transfer regions R and disposing regions (shot) here can be adjusted according to actual needs, and the number of transfer regions R of wafer W may be the same as or different from the number of disposing regions (shot) of substrate S, and this disclosure does not limit the specific number. Here, each disposing region (shot) on the substrate S represents the maximum range of the disposing region of the transferred electronic component matrix MX during a single mass transfer. With different process technologies, the size of the disposing region (shot) may also change. For example, the electronic component matrix MX in FIG. 1 contains a plurality of light emitting diodes (LEDs) LE, in which a part of the LEDs LE in the electronic component matrix MX in FIG. 1 is transferred into the disposing region (shot) in FIG. 2, for example, the LED array blackened in FIG. 1 is transferred into the disposing region (shot) in FIG. 2. However, the above description is only an embodiment of the present disclosure, and the present disclosure is not limited to this.

Take FIG. 1 and FIG. 2 as examples to illustrate the shot mura problem. For example, in the manufacturing process, the LED matrix in a certain region on the wafer W (assumed to be the transfer region R13, but it is only an example, and this disclosure is not limited to this) has a brightness distribution, and then the LED matrix in the transfer region R13 is repeatedly arranged to the adjacent disposing region (shot) on the substrate S of the display by a mass transfer method. For example, the electronic component matrix MX in FIG. 1 includes a plurality of light emitting diodes (LEDs) LE, in which a part of the electronic component matrix MX in the transfer region R13 in FIG. 1 is transferred into the disposing region (shot) in FIG. 2, for example, the LED LE blacked out in FIG. 1 is transferred into the disposing region (shot) in FIG. 2. Subsequently, the light emitting diode LE of another part of the electronic component matrix MX in the transfer region R13 in FIG. 1 is transferred to another disposing region (shot) in FIG. 2. The above description is only an embodiment of the present disclosure, and the present disclosure is not limited to this.

After the mass transfer, since the light emitting diodes LE from the transfer region R13 are repeatedly arranged in the adjacent disposing regions (shot), it is easy for users to feel that the same brightness distribution will appear in the regions where these disposing regions (shot) are located at a fixed frequency. Furthermore, when the substrate S of the display is covered with the light emitting diodes LE transferred by the above transfer method, the user can easily find the region with the same brightness distribution at a fixed frequency on the substrate S, that is, the shot mura problem of the display.

In order to reduce the problem of shot mura, this disclosure provides several methods, which can reduce the probability of users feeling shot mura by adjusting the size or regional distribution of the electronic component matrix MX formed by the arrangement of LED LE during mass transfer.

Please refer to FIG. 3, which shows the distance between a display and a viewer. FIG. 3 contains a display 1 and a user 2, and the diagonal of the display 1 is defined as L. According to the experience of ordinary users, a better viewing experience can be obtained when the distance between the user 2 and the display 1 is 3 L, while the range that can be effectively recognized by human eyes is about 6 degrees (represented by viewing angle α in the figure). Therefore, from FIG. 3, when the distance between the user 2 and the display 1 is 3 L and the user 2 faces the display 1, the sensitive viewing angle range is about an region with the length and width of 3 L tan(6°)=0.315 L. That is to say, according to the past user's experience, when the user 2 looks at the display 1, although the user can perceive the whole picture of the display 1, the sensitive visual angle range does not cover the whole display 1, but only within the sensitive visual angle range (a circular range with a diameter of 0.315 L centered on the gaze point) can the user feel the subtle changes of the display 1. In other words, the slight change is not easy to be found by the user in the range beyond 0.315 L from the user's gaze point.

Therefore, one of the methods to reduce shot mura provided by this disclosure is to adjust the length and width of the electronic component matrix MX formed by the arrangement of light emitting diodes LE to be greater than or equal to 0.315 L. Taking FIG. 2 and FIG. 3 as examples, an electronic component matrix MX is defined as M along the horizontal direction (X direction) and N along the vertical direction (Y direction). When the size of the electronic component matrix MX is set to be greater than or equal to 0.315 L, that is, when M is greater than or equal to 0.315 L and N is greater than or equal to 0.315 L, it means that when the user 2 looks at the display 1, the sensitive viewing angle range will not exceed the range of a single electronic component matrix MX, so the electronic component matrices MX in multiple repeatedly arranged disposing regions (shot) will not appear in the sensitive viewing angle range of the user, and this design makes it difficult for the user to identify the brightness difference of the electronic component matrices MX between different disposing regions (shot), which can improve the user experience. In short, in this embodiment, the size of each disposing region of the display is set to exceed the sensitive visual angle range of human eyes, so as to reduce the probability that users feel shot mura. Specifically, a group of electronic components (e.g., light emitting diodes (LEDs) LE) in one transfer region R (e.g., transfer region R13) on the wafer W are transferred to one disposing region (shot) on the substrate S. The LEDs LE can be arranged in an electronic component matrix MX and set in the disposing region (shot), and the size of the electronic component matrix MX can be defined by the distance between the center points of the LEDs LE at the four corners of the matrix. The length M of the electronic component matrix MX in the horizontal direction should be close to but smaller than the dimension M′ of the disposing region (shot) in the horizontal direction, and the length N in the vertical direction should be close to but smaller than the dimension N′ of the disposing region (shot) in the vertical direction. Because if the size of the electronic component matrix MX in a certain direction is larger than that of the disposing region (shot) in the same direction, there will be interference between adjacent electronic component matrices MX, and when the size of the electronic component matrix MX is much smaller than that of the disposing region (shot) in the same direction, it is easy for users to observe the gaps formed by different electronic component matrices MX between adjacent disposing regions (shot).

The second method for reducing shot mura provided by the second embodiment of this disclosure is contrary to the first method, that is, setting the size of each electronic component matrix MX to be less than the visual recognition limit of human eyes can blur the visual field, thereby reducing the occurrence probability of shot mura. Furthermore, according to the applicant's experiments and past users' experience statistics, when the spatial frequency is higher than 15 cycle/degree in each viewing angle range (that is, the number of the same object shows more than 15 times in one viewing angle range), the human eye will automatically mix and blur the patterns with high frequency changes (for example, when the red, green and blue light sources appear repeatedly, the human eye will automatically mix them into white light). Taking this embodiment as an example, when the diagonal of the display 1 is 1 and the distance between the user 2 and the display 1 is 3 L, the viewing angle range of 1 degree is 3 L tan(1°)=0.052 L, because the human eye will automatically blur the pattern when the spatial frequency is higher than 15 cycles/degree, so if the range of the electronic component matrix MX is less than 0.052 L/15=0.0035 L, it is within the viewing angle range observed by the human eye. In short, this method sets the size of each electronic component matrix MX to be less than the visual recognition limit of human eyes, so as to reduce the probability of users feeling shot mura.

The third method for reducing shot mura provided by the third embodiment of the present disclosure is to reduce the probability of shot mura by adjusting the shot distribution of the electronic component matrix MX transferring to the disposing region on the substrate S of the display during mass transfer. In more detail, as mentioned in the previous paragraph, when the light emitting diodes LE in some specific transfer regions R (for example, R13, but this is only an example, and this disclosure is not limited to this) on the wafer W have specific brightness distributions, if they are repeatedly arranged in the adjacent disposing region (shot) of the display S after a mass transfers, the same brightness distribution will appear in this region at a fixed frequency, which is the aforementioned shot mura phenomenon. In order to reduce the situation of shot mura during mass transfer, it is necessary to adjust the position of transferring electronic components (such as LED LE) to the substrate S during mass transfer. Generally speaking, when electronic components from the same transfer region R on the wafer W (take transfer region R13 as an example, but this is only an example, and this disclosure is not limited to this) are arranged in the disposing region (shot) on the substrate S, the electronic component matrices MX from the same transfer region R on the wafer W are arranged as non-adjacent as possible. That is to say, if an electronic component matrix MX formed by a group of electronic components from the transfer region R13 on the wafer W is selected for a certain disposing region (shot) on the substrate S, another electronic component matrix MX formed by another group of electronic components from the same transfer region R13 will be transferred to another non-adjacent disposing region (shot) at the next transfer, and electronic components from other non-transfer regions R13 of the wafer W are preferably selected for adjacent disposing regions (shot). In this way, the situation that electronic components corresponding to the same brightness distribution are repeatedly arranged in adjacent regions in the substrate S can be reduced.

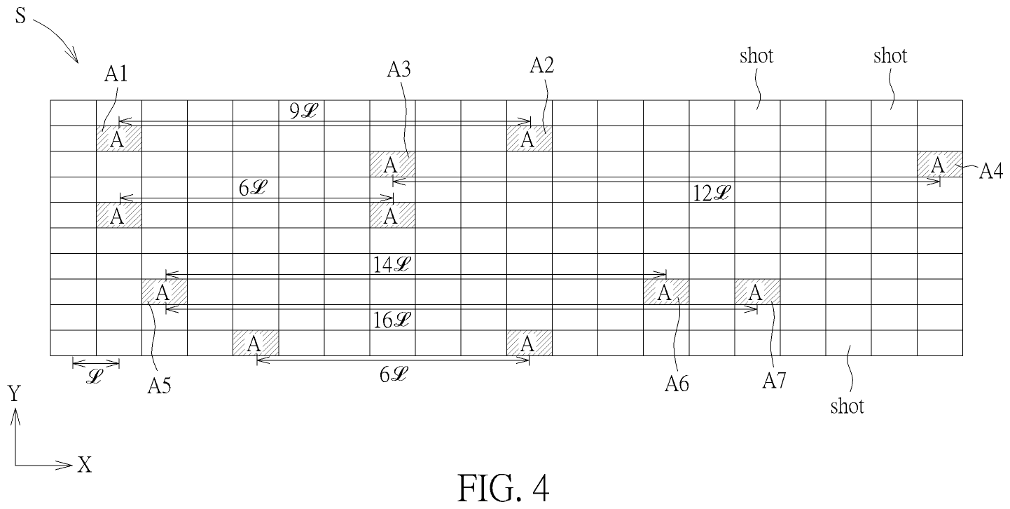

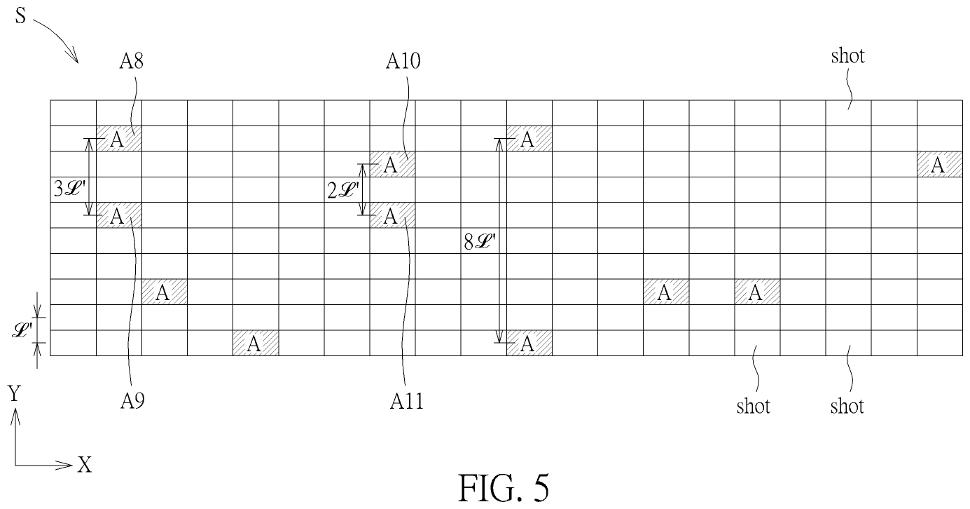

In addition, reference can also be made to FIG. 4 and FIG. 5 at the same time. FIG. 4 shows the distribution distance of the disposing region (shot) on a substrate in the horizontal direction, and FIG. 5 shows the distribution distance of the disposing region (shot) on a substrate in the vertical direction. As shown in FIG. 4 and FIG. 5, the substrate shown in FIG. 4 and FIG. 5 can refer to the substrate S shown in FIG. 2, which is also a grid matrix with 20 columns and 10 rows, each grid represents a disposing region (shot). It can be understood that the number of disposing regions (i.e., squares shown on the drawing) in this embodiment can be adjusted according to requirements, and this embodiment only shows an example.

In FIG. 4 and FIG. 5, the distance between two adjacent disposing regions (shot) in the X direction (the distance from the center of one disposing region (shot) to the center of another disposing region (shot) adjacent in the X direction) is represented as [symbol] . When the disposing region (shot) is rectangular, [symbol] can be equal to the dimension M′ in FIG. 2, while [symbol] ′ represents the distance between two adjacent disposing regions in the Y direction (the distance from the center of one disposing region (shot) to the center of another disposing region (shot) adjacent in the Y direction. When the disposing region (shot) is rectangular, [symbol] ′ may be equal to the dimension N′ in FIG. 2. As shown in FIG. 4 and FIG. 5, in each disposing region (shot), the disposing region (shot) containing the electronic component matrix from the same transfer region on the wafer W is denoted by the same reference number. For example, some disposing regions (shot) contain the electronic component matrix from the transfer region R13 on the wafer W (for example, the electronic component matrix MX in FIG. 1), and these disposing regions (shot) are marked as disposing region A for easy identification. It is worth noting that other disposing regions (shot) should also contain electronic components, but they are not marked here for the sake of simplicity.

Please refer to FIG. 4 first. It can be seen that the distance between two adjacent disposing regions Ain the same row is not the same as that between two adjacent disposing regions A in another row in the X direction. For example, in FIG. 4, the disposing region A in the first row (the uppermost row) does not include the disposing region A. The distance from the disposing region A (or labeled as disposing region A1) in the second row to another disposing region A (or labeled as disposing region A2) in the same row is 9 [symbol] , while the distance from the disposing region A (or labeled as disposing region A3) in the third row to another disposing region A (or labeled as disposing region A4) in the same row is 12 [symbol] . It should be noted that when the electronic components from the same transfer region R on the wafer W are arranged in different rows, the distance between the electronic components and the disposing regions A in other rows should not be duplicated as much as possible, so as to avoid the situation that the disposing regions A in different rows are adjacent to each other and the same brightness distribution is observed repeatedly due to the distance duplication. Similarly, the other fourth, fifth and sixth rows are also arranged according to this rule. In addition, it is also possible to include more than two disposing regions A in the same row, and the distances between adjacent disposing regions A are different from each other. For example, in FIG. 4, the eighth row has three disposing regions A, which are respectively marked as disposing region A5 containing a first group of electronic components from the same transfer region, disposing region A6 containing a second group of electronic components from the same transfer region and disposing region A7 containing a third group of electronic components from the same transfer region, the distance between the disposing region A5 and the disposing region A6 is different from the distance between the disposing region A6 and the disposing region A7.

Similarly, the distance between the disposing region A in each column in FIG. 5 and the disposing region A in the same column is also different from the distance between the disposing regions A in other columns and the adjacent disposing regions A. For example, in FIG. 5, the distance from the disposing region A (labeled as the disposing region A8) in the second column to another disposing region A (labeled as the disposing region A9) in the same column is 3 [symbol] ′, while in FIG. 5, the distance from the disposing region A (labeled as the disposing region A10) in the eighth column to another disposing region A (labeled as the disposing region A11) in the same column is 2 [symbol] ′. It should be noted that when the electronic components from the same transfer region R on the wafer W are arranged in different columns, the distance between the electronic components and the disposing regions A in other columns should not be duplicated as much as possible

It is worth noting that in the above-mentioned substrates of FIG. 4 and FIG. 5, a grid array with 20 columns and 10 rows is taken as an example. However, if the size of the substrate increases or the number of disposing regions increases, it may be difficult to achieve that the distance between each disposing region A and another disposing region A in the same column/or row does not repeated with each other, so the distance between some disposing regions A and adjacent disposing regions A may still repeat with the distance of other columns/rows. However, if the distance between different columns and/or rows is larger than the sensitive visual angle range of human eyes (that is, the above-mentioned visual angle range of about 6 degrees), the influence caused by repeated arrangement can be reduced. For example, in FIG. 4, the distance between the disposing region A in the fifth row and another disposing region A in the same row is 6 [symbol] , and the distance between the disposing region A in the tenth row and another disposing region A in the same row is also 6 [symbol] . However, if the distance between the fifth row and the tenth row is larger than the visual angle range of human eyes of 6 degrees, the influence caused by repeated arrangement can be reduced.

In addition, FIG. 4 and FIG. 5 only show the distance difference between the disposing regions (shot) in a single direction (horizontal direction X or vertical direction Y), but the present disclosure is not limited to this. In some embodiments, the distance difference between two disposing regions in the horizontal direction X and the vertical direction Y can be considered at the same time.

Therefore, by controlling the distribution of a mass transferred electronic components in the above manner, the disposing regions (shot) where electronic components including the same region R on the wafer W are transferred to the substrate are not adjacent to each other, and these disposing regions (shot) will not be arranged repeatedly. That is to say, the regularity of arrangement is visually broken, and the electronic components in a specific region are not repeatedly or centrally arranged in the adjacent region of the substrate S as far as possible, so that the effect of reducing shot mura can be achieved.

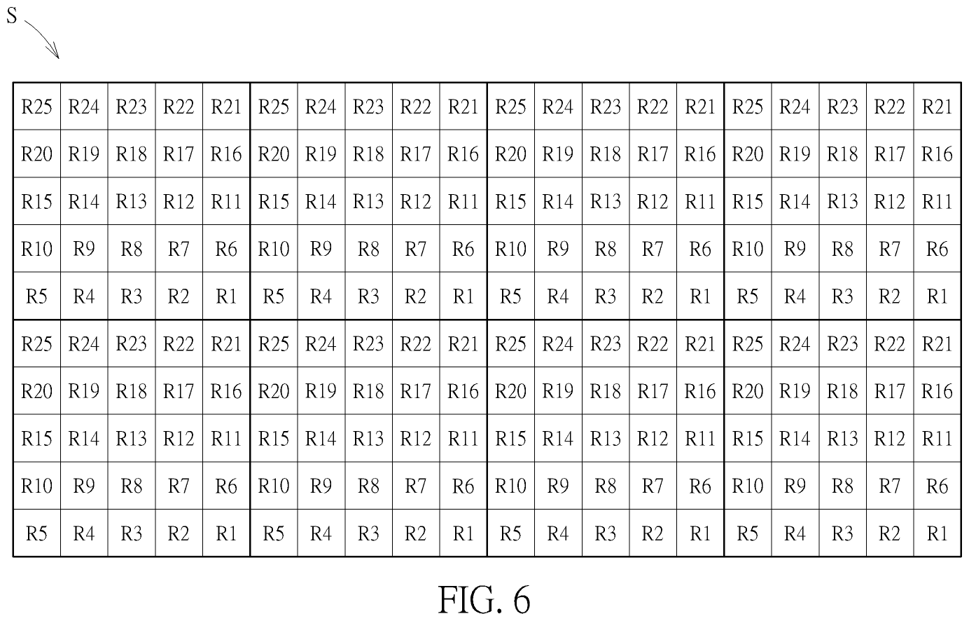

The fourth method for reducing shot mura provided by the fourth embodiment of the present disclosure is to copy the relative position of the transfer region R on the wafer W to the relative position of each disposing region (shot) of the substrate S during mass transfer. For example, each transfer region R of the wafer W in FIG. 1 is labeled R1-R25 respectively, and each transfer region R may include a plurality of electronic components (such as light emitting diodes (LEDs) LE). When electronic components on the wafer W are transferred to the substrate S through mass transfer, the electronic component matrix MX of the first transfer region R1 is transferred to the first disposing region (shot) on the substrate S, and the electronic component matrix MX of another transfer region (for example, transfer region R13) is transferred to another disposing region (shot) on the substrate S, and the relative positions of these two disposing regions (shot) are the same as those of the two transfer regions (for example, R1 and R13). As shown in FIG. 6, FIG. 6 shows a schematic diagram of a substrate after mass transfer according to an embodiment of the present disclosure. The relative positional relationship between the disposing regions (shot) on the substrate S is also the same as that of the transfer regions R1-R25 on the wafer W. The reason for this is that, because the parameters of each process condition change gradually in the process of manufacturing electronic components on the wafer, it is not easy for the brightness of electronic components in adjacent regions to suddenly change obviously on the wafer W. Therefore, if the distribution of electronic components in each transfer region R1-R25 on the wafer W is copied to each disposing region (shot) on the substrate S, it can also reduce the obvious brightness difference between adjacent disposing regions (shot). This method can also achieve the effect of reducing shot mura.

The third method and the fourth method of this disclosure can be applied when the length or width of the disposing region (shot) is less than 0.315 L and more than 0.0035 L. Outside this range, the size of the disposing region will be beyond the sensitive visual angle range of human eyes or less than the visual recognition limit of human eyes (respectively, the first method and the second method described in this disclosure), so it is difficult for human eyes to find the problem of shot mura. However, the present disclosure is not limited to this. In some embodiments, the third method and the fourth method are also applicable to the case where the length or width of the disposing region (shot) is greater than or equal to 0.315 L or less than or equal to 0.0035 L.

Based on the above description and drawings, the present disclosure provides a manufacturing method of an electronic device, which includes providing a first substrate (such as a wafer W), the first substrate includes a plurality of transfer regions R (the transfer regions R1-R25), and each transfer region includes a plurality of electronic components (such as the light-emitting elements or the light-emitting diodes LE), picking up a first group of electronic components from one of the transfer regions, and transferring the first group of electronic components to a target substrate (i.e., the substrate S), the diagonal length of the target substrate is L, and the first group of electronic components are arranged in an electronic component matrix MX, which is arranged in a disposing region (shot), and the length M of the electronic component matrix MX in a horizontal direction is greater than or equal to 0.315 L and less than L.

In some embodiments of the present disclosure, the length N of the electronic component matrix MX in a vertical direction is greater than or equal to 0.315 L and less than L.

In some embodiments of the present disclosure, the plurality of electronic components include a plurality of light emitting diodes LE.

The present disclosure also provides a manufacturing method of an electronic device, which comprises providing a first substrate (the wafer W), the first substrate comprises a plurality of transfer regions R (the transfer regions R1-R25), and each transfer region comprises a plurality of electronic components (such as the light emitting diodes LE), picking up a first group of electronic components from one of the transfer regions, transferring a first group of electronic components to a first region (one of the disposing regions (shot)) on a target substrate (the substrate S), picking up a second group of electronic components from one of the transfer regions, and transferring the second group of electronic components to a second region (another disposing region (shot)) on the target substrate, the first region and the second region are not adjacent to each other.

In some embodiments of the present disclosure, it further includes picking up a third group of electronic components from one of the transfer regions, and transferring the third group of electronic components to a third region (another disposing region (shot)) on a target substrate. The distance between the first region and the second region is different from the distance between the second region and the third region (for example, refer to FIG. 4, the distance between the disposing region A5 and the disposing region A6 is different from the distance between the disposing region A6 and the disposing region A7).

In some embodiments of the present disclosure, it further includes picking up a third group of electronic components from one of the transfer regions, transferring the third group of electronic components to a third region (another disposing region (shot)) on a target substrate, picking up a fourth group of electronic components from one of the transfer regions, and transferring the fourth group of electronic components to a fourth region (another disposing region (shot)) on the target substrate.

In some embodiments of the present disclosure, the first region and the second region are located on one column of the target substrate, the third region and the fourth region are located on another column of the target substrate, and the distance between the first region and the second region is different from the distance between the third region and the fourth region (for example, refer to FIG. 4, the distance between the disposing region A1 and the disposing region A2 is different from the distance between the disposing region A3 and the disposing region A4).

In some embodiments of the present disclosure, the first region and the second region are located on one row of the target substrate, and the third region and the fourth region are located on another row of the target substrate, and the distance between the first region and the second region is different from that between the third region and the fourth region (for example, refer to FIG. 5, the distance between the disposing region A8 and the disposing region A9 is different from that between the disposing region A10 and the disposing region A11).

In some embodiments of the present disclosure, the diagonal length of the target substrate is L, the first group of electronic components are arranged in a matrix (i.e., an electronic component matrix MX), and the length M of the matrix in a horizontal direction is less than 0.315 L and greater than 0.0035 L.

The present disclosure also provides a manufacturing method of an electronic device, which comprises providing a first substrate (the wafer W), the first substrate comprises a plurality of transfer regions R (the transfer regions R1-R25), each transfer region comprises a plurality of electronic components, picking up a first group of electronic components from a first transfer region (one of the transfer regions R1-R25) of the transfer regions, transferring a first group of electronic components to a first region (one of the disposing regions (shot)) on a target substrate (the substrate S), picking up a second group of electronic components from a second transfer region (the other of transfer regions R1-R25) of these transfer regions, and transferring the second group of electronic components to a second region (the other of disposing regions (shot)) on the target substrate. The relative positions of the first transfer region and the second transfer region on the first substrate are the same as those of the first region and the second region on the target substrate (refer to the embodiment described in FIG. 6).

To sum up, this disclosure provides several different methods to solve the shot mura problem of the current display. The methods described in this disclosure are compatible with the existing processes, and can effectively solve the shot mura problem of the display without increasing a lot of costs and additional processes, and improve the quality of products and the viewing experience of users.

The feature among that embodiments of the present disclosure can be mix and matched at will as long as they do not violate the disclosure spirit or conflict with each other.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of an electronic device, comprising:
providing a first substrate, wherein the first substrate comprises a plurality of transfer regions, and each transfer region comprises a plurality of electronic components;
picking up a first group of electronic components from one of the transfer regions; and
transferring the first group of electronic components to a target substrate;
wherein the diagonal length of the target substrate is L, the first group of electronic components are arranged in a matrix, and the length M of the matrix in a horizontal direction is greater than or equal to 0.315 L and less than L.

2. The method for manufacturing an electronic device according to claim 1, wherein the length N of the matrix in a vertical direction is greater than or equal to 0.315 L and less than L.

3. The method for manufacturing an electronic device according to claim 1, wherein the plurality of electronic components comprise a plurality of light emitting diodes.

4. The method for manufacturing an electronic device according to claim 1, wherein the first substrate comprises a wafer.

5. The method for manufacturing an electronic device according to claim 1, wherein the target substrate comprises a substrate of a display.

6. The method for manufacturing an electronic device according to claim 1, wherein the electronic components in each transfer region of the first substrate are arranged in a matrix.

7. The method for manufacturing an electronic device according to claim 6, wherein the target substrate comprises a plurality of disposing regions, and the first group of electronic components are arranged in the matrix, wherein the size of the matrix is smaller than the size of each disposing region.

8. A manufacturing method of an electronic device, comprising:
providing a first substrate, wherein the first substrate comprises a plurality of transfer regions, and each transfer region comprises a plurality of electronic components;
picking up a first group of electronic components from one of the transfer regions;
transferring the first group of electronic components to a first region on a target substrate;
picking up a second group of electronic components from one of the transfer regions; and
transferring the second group of electronic components to a second region on the target substrate;
wherein the first region and the second region are not adjacent to each other.

9. The method for manufacturing an electronic device according to claim 8, further comprising:
picking up a third group of electronic components from one of the transfer regions; and
transferring the third group of electronic components to a third region on the target substrate;
wherein the distance between the first region and the second region is different from the distance between the second region and the third region.

10. The method for manufacturing an electronic device according to claim 8, wherein the first region, the second region and the third region are located in the same row on the target substrate.

11. The method for manufacturing an electronic device according to claim 8, further comprising:
picking up a third group of electronic components from one of the transfer regions;
transferring the third group of electronic components to a third region on a target substrate;
picking up a fourth group of electronic components from one of the transfer regions; and
transferring the fourth group of electronic components to a fourth region on the target substrate.

12. The method for manufacturing an electronic device according to claim 11, wherein the first region and the second region are located on one column of the target substrate, and the third region and the fourth region are located on another column of the target substrate, and the distance between the first region and the second region is different from the distance between the third region and the fourth region.

13. The method for manufacturing an electronic device according to claim 11, wherein the first region and the second region are located on one row of the target substrate, and the third region and the fourth region are located on another row of the target substrate, and the distance between the first region and the second region is different from the distance between the third region and the fourth region.

14. The method for manufacturing an electronic device according to claim 8, wherein the diagonal length of the target substrate is L, and the first group of electronic components are arranged in a matrix, and the length M of the matrix in a horizontal direction is less than 0.315 L and more than 0.0035 L.

15. The method for manufacturing an electronic device according to claim 8, wherein the first substrate comprises a wafer.

16. The method for manufacturing an electronic device according to claim 8, wherein the target substrate comprises a substrate of a display.

17. The method for manufacturing an electronic device according to claim 8, wherein the plurality of electronic components comprise a plurality of light emitting diodes.

18. A manufacturing method of an electronic device, comprising:
providing a first substrate, wherein the first substrate comprises a plurality of transfer regions, and each transfer region comprises a plurality of electronic components;
picking up a first group of electronic components from a first transfer region of the transfer regions;
transferring the first group of electronic components to a first region on a target substrate;
picking up a second group of electronic components from a second transfer region of the transfer regions; and
transferring the second group of electronic components to a second region on the target substrate;
wherein the relative positions of the first transfer region and the second transfer region on the first substrate are the same as the relative positions of the first region and the second region on the target substrate.

19. The method for manufacturing an electronic device according to claim 18, further comprising:
picking up a third group of electronic components from a third transfer region of the transfer regions; and
transferring the third group of electronic components to a third region on the target substrate;
wherein the relative positions of the first transfer region and the third transfer region on the first substrate are the same as the relative positions of the first region and the third region on the target substrate.

20. The method for manufacturing an electronic device according to claim 18, wherein the first substrate comprises a wafer.
